(19) United States
(12) Patent Application Publication
(10) Pub. No.: US 2020/0098939 A1
(43) Pub. Date: Mar. 26, 2020

(54) SOLAR CELL AND METHOD OF MANUFACTURING SOLAR CELL

(71) Applicant: PANASONIC CORPORATION, Osaka (JP)

(72) Inventors: Izuru NAKAI, Osaka (JP); Daiji KANEMATSU, Osaka (JP); Koichi HIRANO, Osaka (JP)

(21) Appl. No.: 16/560,864

(22) Filed: Sep. 4, 2019

(30) Foreign Application Priority Data
Sep. 26, 2018 (JP) 2018-180893

(51) Int. Cl. H01L 31/0224; H01L 31/0216; H01L 31/0236; H01L 31/0747; H01L 31/20; B23K 26/364

(52) U.S. Cl. CPC H01L 31/022441; H01L 31/02168; H01L 31/02363; B23K 26/364; H01L 31/202; H01L 31/208; H01L 31/0747

(57) ABSTRACT

A method of manufacturing a solar cell includes: forming a metal layer on a semiconductor substrate; forming a resist layer on the metal layer, the resist layer including a resin and inorganic particles having a higher optical absorptance at a predetermined wavelength than the resin; forming an opening through which the metal layer is exposed, by irradiating the resist layer with a laser light having the predetermined wavelength and removing the resist layer; and wet etching the metal layer exposed in the opening.

### RELATED APPLICATION

Priority is claimed to Japanese Patent Application No. 2018-180893, filed on Sep.26, 2018, the entire content of which is incorporated herein by reference.

### BACKGROUND OF THE INVENTION

### 1. Field of the Invention

The present invention relates to a solar cell and a method of manufacturing a solar cell.

### 2. Description of the Related Art

Solar cells having high power generation efficiency include back contact type solar cells in which both an n-type semiconductor layer and a p-type semiconductor layer are formed on a back surface of the cell opposite to a light-receiving surface on which light is incident. An n-side electrode is formed on the n-type semiconductor layer and a p-side electrode is formed on the p-type semiconductor layer. An isolation groove for electrical insulation is provided between the n-side electrode and the p-side electrode. There is known a method of forming an isolation groove between electrodes by using ablation caused by laser irradiation.

From the perspective of improving the efficiency of collecting power, it is preferred to configure the isolation groove between electrodes to have a small width.

The disclosure addresses the above-described issue, and a general purpose thereof is to provide a solar cell having a higher power generation efficiency.

### SUMMARY OF THE INVENTION

A method of manufacturing a solar cell according to an embodiment of the present disclosure includes: forming a metal layer on a semiconductor substrate; forming a resist layer on the metal layer, the resist layer including a resin and inorganic particles having a higher optical absorptance at a predetermined wavelength than the resin; forming an opening through which the metal layer is exposed, by irradiating the resist layer with a laser light having the predetermined wavelength and removing the resist layer; and wet etching the metal layer exposed in the opening.

Another embodiment of the present disclosure relates to a solar cell. The solar cell includes: a semiconductor substrate; a first conductivity type semiconductor layer provided in a first region on the semiconductor substrate; an insulating layer provided in a partial region adjacent to the first region on the first conductivity type semiconductor layer; a second conductivity type semiconductor layer provided in a second region on the semiconductor substrate adjacent to the first region and provided on the insulating layer; a metal layer provided on the first conductivity type semiconductor layer, the insulating layer, and the second conductivity type semiconductor layer; and a resist layer that is provided on the metal layer and includes a resin and inorganic particles. The metal layer and the resist layer have an opening that extends through the metal layer or the resist layer at a position overlapping the insulating layer. The opening of the resist layer is tapered such that an opening width grows smaller toward the metal layer.

### BRIEF DESCRIPTION OF THE DRAWINGS

Embodiments will now be described by way of examples only, with reference to the accompanying drawings which are meant to be exemplary, not limiting and wherein like elements are numbered alike in several Figures in which:

FIG. 1 is a plan view showing the structure of a back surface of a solar cell according to the embodiment;

FIG. 2 is a cross-sectional view showing the structure of the solar cell FIG. 1;

FIG. 3 schematically shows a step of manufacturing a solar cell;

FIG. 4 schematically shows a step of manufacturing a solar cell;

FIG. 5 schematically shows a step of manufacturing a solar cell;

FIG. 6 schematically shows a step of manufacturing a solar cell;

FIG. 7 schematically shows a step of manufacturing a solar cell;

FIG. 8 schematically shows a step of manufacturing a solar cell;

FIG. 9 schematically shows a step of manufacturing a solar cell;

FIG. 10 schematically shows a step of manufacturing a solar cell;

FIGS. 11A-11C schematically show a step of forming an opening in the resist layer by laser irradiation;

FIG. 12 shows the workability with which to work the opening by laser irradiation that results when the density of inorganic particles included in the resist layer is changed; and

FIG. 13 is a cross-sectional view showing the structure of the solar cell according to a variation.

### DETAILED DESCRIPTION OF THE INVENTION

The invention will now be described by reference to the preferred embodiments. This does not intend to limit the scope of the present invention, but to exemplify the invention.

A brief summary will be given before describing an embodiment in specific details. The embodiment relates to a back contact type solar cell. A solar cell includes: a semiconductor substrate; a first conductivity type semiconductor layer provided in a first region on the semiconductor substrate; an insulating layer provided in a partial region adjacent to an edge of the first region on the first conductivity type semiconductor layer, a second conductivity type semiconductor layer provided in a second region on the semiconductor substrate adjacent to the first region and also provided on the insulating layer; a metal layer provided on the first conductivity type semiconductor layer, the insulating layer, and the second conductivity type semiconductor layer. The metal layer forms at least a part of the n-side electrode and the p-side electrode of the solar cell. An isolation groove to secure electrical insulation between the n-side electrode and the p-side electrode is provided in the metal layer. The isolation groove is formed by forming a resist layer on the metal layer, removing the resist layer by irradiating the resist layer with a laser light having a predetermined wavelength, forming an opening through which the metal layer is exposed, and wet etching the metal layer exposed through the opening. According to the embodiment, an isolation groove having a small isolation width is formed at a low cost by using a resist layer including a resin and inorganic particles having a higher optical absorptance at the predetermined wavelength than the resin.

A detailed description will be given of an embodiment to practice the present disclosure with reference to the drawings. In the explanations of the figures, the same elements shall be denoted by the same reference numerals, and duplicative explanations will be omitted appropriately.

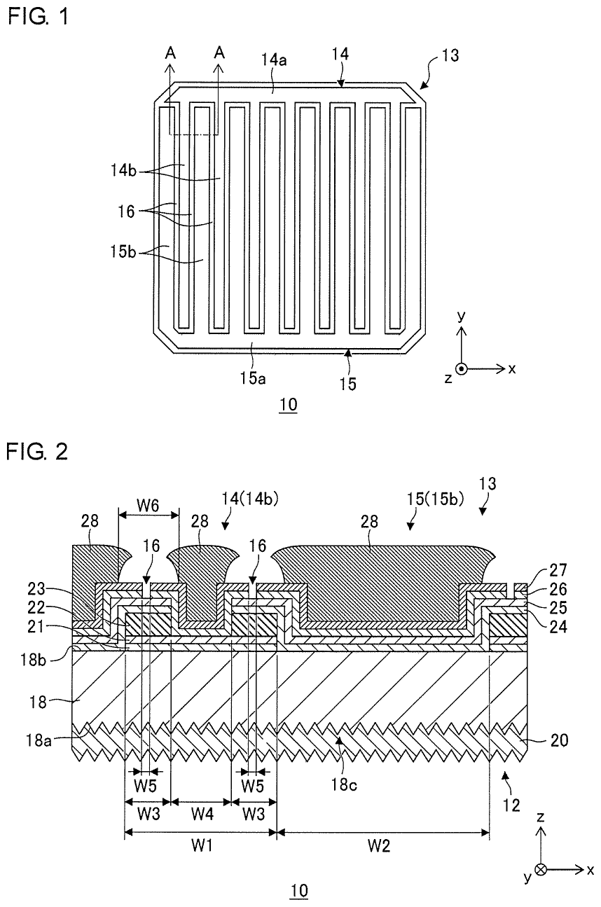

FIG. 1 is a plan view showing a solar cell 10 according to the embodiment and shows the structure of a back surface 13 of the solar cell 10. The solar cell 10 includes a first electrode 14 and a second electrode 15 provided on the back surface 13. The solar cell 10 is a so-called back contact type solar cell. No electrodes are provided on the side of the light-receiving surface, and the first electrode 14 and the second electrode 15 having different polarities are both provided on the back surface 13 opposite to the light-receiving surface. Between the first electrode 14 and the second electrode 15 is provided an isolation groove 16 for electrically insulating the electrodes.

The first electrode 14 includes a first bus bar electrode 14a extending in the x direction and a plurality of first finger electrodes 14b extending in the y direction intersecting the first bus bar electrode 14a and is formed in a comb-tooth shape. The second electrode 15 includes a second bus bar electrode 15a extending in the x direction and a plurality of second finger electrodes 15b extending in the y direction intersecting the second bus bar electrode 15a and is formed in a comb-tooth shape. The first electrode 14 and the second electrode 15 are formed such that the comb teeth of the electrodes are in mesh with each other and inserted into each another. Each of the first electrode 14 and the second electrode 15 may be a busbar-less electrode consisting only of a plurality of fingers and having no busbars.

FIG. 2 is a cross-sectional view showing the structure of the solar cell 10 according to the embodiment and shows an A-A cross section of FIG. 1. The solar cell 10 includes a substrate 18, a light-receiving surface protection layer 20, a first amorphous layer 21, a first conductivity type semiconductor layer 22, an insulating layer 23, a second amorphous layer 24, a second conductivity type semiconductor layer 25, a transparent electrode layer 26, a metal layer 27, and a plating layer 28.

The solar cell 10 includes a light-receiving surface 12 and a back surface 13. The light-receiving surface 12 means a principal surface on which light (sunlight) is mainly incident in the solar cell 10 and, specifically, means a surface on which the major portion of light entering the solar cell 10 is incident. The back surface 13 means the other principal surface opposite to the light-receiving surface 12.

The substrate 18 is formed by a crystalline semiconductor having the first conductivity. Specific examples of the crystalline semiconductor substrate include a crystalline silicon (Si) wafer like a monocrystalline silicon wafer and a polycrystalline silicon wafer. In this embodiment, it is shown that the substrate 18 is an n-type monocrystalline silicon wafer having the first conductivity type, and the first conductivity type is the n-type, and the second conductivity type is the p-type. The substrate 18 includes an impurity of the first conductivity type and includes, for example, phosphorus (P) as the n-type impurity to dope silicon. The thickness of the substrate 18 is, for example, 200 μm.

The solar cell may be formed by a semiconductor substrate other than a crystalline silicon wafer. For example, a compound semiconductor wafer made of gallium arsenide (GaAs), indium phosphorus (InP), etc. may be used. Alternatively, the semiconductor substrate may have the second conductivity type or may have the p-type.

The substrate 18 includes a first principal surface 18a on the side of the light-receiving surface 12, and a second principal surface 18b on the side of the back surface 13. The substrate 18 absorbs light incident on the first principal surface 18a and generates electrons and positive holes as carriers. The first principal surface 18a is provided with a texture structure (concave-convex structure) 18c for increasing the efficiency of absorbing incident light. Meanwhile, the second principal surface 18b may not be provided with a texture structure like that of the first principal surface 18a, and the second principal surface 18b may be flatter than the first principal surface 18a. From the perspective of improving the efficiency of collecting power by configuring the groove between the electrodes to have a small isolation width, it is preferred not to work the second principal surface 18b to form a texture structure. In other words, it is preferred to provide a texture structure only on the first principal surface 18a and not to form a texture structure on the second principal surface 18b.

The light-receiving surface protection layer 20 is provided on the first principal surface 18a of the substrate 18. The light-receiving surface protection layer 20 functions as a passivation layer for the first principal surface 18a. The passivation layer may include at least one of a substantially intrinsic amorphous semiconductor layer, an amorphous first conductivity type semiconductor layer, an amorphous second conductivity type semiconductor layer, and an insulating layer. The passivation layer can be made of amorphous silicon containing hydrogen, silicon oxide, silicon nitride, silicon oxynitride, or the like. The passivation layer has a thickness of, for example, about 2 nm-100 nm.

The light-receiving surface protection layer 20 may also have a function of an antireflection film or a protection film. The antireflection film or the protection film can be made of silicon oxide, silicon nitride, silicon oxynitride, or the like. The thickness of the antireflection film or the protection film is configured as appropriate in accordance with, for example, the antireflection property. For example, the thickness is about 50 nm-1100 nm.

A first region W1 and a second region W2 are provided on the second principal surface 18b of the substrate 18. The first region W1 corresponds to a region where the first electrode 14 of FIG. 1 is provided, and the second region W2 corresponds to a region where the second electrode 15 of FIG. 1 is provided. Therefore, the first region W1 and the second region W2 are each formed in a comb-tooth shape and are formed to be inserted into each other. The first region W1 and the second region W2 are arranged to alternate in the x direction.

The first region W1 is on the side of the first conductivity type and collects those of carriers generated in the substrate 18 that are of the first conductivity. Since the substrate 18 is of the first conductivity type, it can be said that the first region W1 is a region that collects majority carriers. Meanwhile, the second region W2 is on the side of the second conductivity type and collects carries of the second conductivity type, i.e., minority carriers. Given that the first conductivity type is the n-type and the second conductivity type is the p-type, the first region W1 collects electrons, and the second region W2 collects holes. The efficiency of collecting minority carriers is lower than that of majority carriers. Accordingly, the area of the second region W2 on the side of minority carriers is configured to be larger than the area of the first region W1 on the side of majority carriers in order to increase the power generation efficiency of the cell as a whole. For example, the width of the first region W1 in the x direction is about 500 μm, and the width of the second region W2 in the x direction is about 700 μm-1000 μm.

The first amorphous layer 21 is provided in the first region W1 on the second principal surface 18b of the substrate 18. The first amorphous layer 21 is made of an i-type or n-type amorphous semiconductor or an insulator. The first amorphous layer 21 is made of, for example, i-type or n-type amorphous silicon containing hydrogen, or a silicon compound or an aluminum compound containing at least one of oxygen and nitrogen. The thickness of the first amorphous layer 21 is about 1 nm-200 nm, and, preferably, about 2 nm-25 nm.

In this specification, a substantially intrinsic semiconductor will be referred to as “i-type semiconductor”. A substantially intrinsic semiconductor includes a semiconductor layer formed without positively using an n-type or p-type impurity element and includes a semiconductor layer formed without supplying a dopant gas during chemical vapor deposition (CVD) etc. Specifically, it includes silicon obtained by supplying silane (SiH₄), etc. diluted with hydrogen (H₂) without supplying a dopant gas such as diborane (B₂H₆) and phosphine (PH₃).

The first conductivity type semiconductor layer 22 is provided on the first amorphous layer 21 in the first region W1. The first conductivity type semiconductor layer 22 is a semiconductor layer including an impurity of the first conductivity type, which is the same conductivity type of the substrate 18, and is, for example, a silicon layer including phosphorous (P). It is preferred that the impurity density of the first conductivity type semiconductor layer 22 be higher than that of the substrate 18. The first conductivity type semiconductor layer 22 has a thickness of, for example, about 2 nm-50 nm. The first conductivity type semiconductor layer 22 is formed by an amorphous or crystalline semiconductor. In the case the first conductivity type semiconductor layer 22 is made of an amorphous semiconductor, the first conductivity type semiconductor layer 22 is made of n-type amorphous silicon containing hydrogen. In the case the first conductivity type semiconductor layer 22 is made of a crystalline semiconductor, the first conductivity type semiconductor layer 22 includes, for example, at least one of n-type monocrystalline silicon, polycrystalline silicon, and microcrystalline silicon. The first conductivity type semiconductor layer 22 may be configured to include both an amorphous portion and a crystalline portion.

The insulating layer 23 is made of an insulating material and is made of, for example, silicon oxide (SiO), silicon nitride (SiN), silicon oxynitride (SiON), or the like. The insulating layer 23 is provided on the first conductivity type semiconductor layer 22. The insulating layer 23 is provided in a partial region (third region) W3 adjacent to the edge (outer circumference) of the first region W1 and is not provided in a fourth region W4 corresponding to the central part of the first region W1. The x-direction width of the third region W3 in which the insulating layer 23 is provided is about ⅓ the x-direction width of the first region W1. The x-direction width of the fourth region W4 in which the insulating layer 23 is not provided is also about ⅓ the x-direction width of the first region W1. For example, the x-direction width of each of the third region W3 and the fourth region W4 is about 150 μm-200 μm.

The second amorphous layer 24 is provided in the second region W2 on the second principal surface 18b of the substrate 18 and in the third region W3 on the insulating layer 23. The second amorphous layer 24 is made of an i-type or p-type amorphous semiconductor or an insulator. The second amorphous layer 24 is made of, for example, i-type or p-type amorphous silicon containing hydrogen, or a silicon compound or an aluminum compound including at least one of oxygen and nitrogen. The thickness of the second amorphous layer 24 is about 1 nm-200 nm, and, preferably, about 2 nm-25 nm.

The second conductivity type semiconductor layer 25 is provided on the second amorphous layer 24 in the second region W2 and in the third region W3. The second conductivity type semiconductor layer 25 is a semiconductor layer including an impurity of the second conductivity type different from the first conductivity type and is, for example, a silicon layer including boron (B). The second conductivity type semiconductor layer 25 has a thickness of, for example, about 2 nm-50 nm. The second conductivity type semiconductor layer 25 is formed by an amorphous or crystalline semiconductor and includes p-type amorphous silicon containing hydrogen, or at least one of p-type monocrystalline silicon, polycrystalline silicon, and microcrystalline silicon. The second conductivity type semiconductor layer 25 may be configured to include both an amorphous portion and a crystalline portion.

The transparent electrode layer 26 is formed on the first conductivity type semiconductor layer 22 in the fourth region W4 and on the second conductivity type semiconductor layer 25 in the second region W2 and in the third region W3. The transparent electrode layer 26 is formed by, for example, a transparent conductive oxide (TCO) such as tin oxide (SnO₂), zinc oxide (ZnO), and indium tin oxide (ITO) that is doped with tin (Sn), antimony (Sb), fluorine (F), aluminum, etc. The thickness of the transparent electrode layer 26 may be, for example, about 50 nm-100 nm.

The metal layer 27 is provided on the transparent electrode layer 26. The metal layer 27 is a conductive material layer containing a metal such as copper (Cu), tin (Sn), gold (Au), silver (Ag), nickel (Ni), and titanium (Ti). The metal layer 27 is a seed layer to form the plating layer 28 and has a thickness of, for example, about 50 nm-1100 nm.

An isolation groove 16 is provided in the transparent electrode layer 26 and the metal layer 27. The isolation groove 16 is located in the third region W3 in which the insulating layer 23 is provided. The width of an isolation region W5 in which the isolation groove 16 is provided is smaller than the width of the third region W3. The x-direction width of the isolation region W5 is equal to or smaller than ½, and, preferably, equal to or smaller than ⅓, the x-direction width of the third region W3. The x-direction width of the isolation region W5 is, for example, about 20 μm-60 μm.

The plating layer 28 is provided on the metal layer 27. The plating layer 28 includes a metal such as copper (Cu), tin (Sn), gold (Au), silver (Ag), nickel (Ni), and titanium (Ti) and is configured to include a material common to the metal layer 27. The plating layer 28 is not provided in the isolation region W5 in which the isolation groove 16 is located. The plating layer 28 is provided in a resist region W6 located to correspond to the third region W3, in such a manner that the plating layer 28 is not in contact with the metal layer 27.

The resist region W6 corresponds to a region in which a resist layer for patterning the plating layer 28 is provided. The resist region W6 is a region wider than the isolation region W5, and the entirety of the isolation region W5 is included inside the resist region W6. The resist region W6 may be configured to be aligned with the third region W3, configured to be located only inside the third region W3, or configured to overlap the edge of the third region W3 at least in part. The resist region W6 may overlap the second region W2 and the fourth region W4 adjacent to the third region W3.

In this embodiment, each of the first electrode 14 and the second electrode 15 is comprised of the transparent electrode layer 26, the metal layer 27, and the plating layer 28. The first electrode 14 collects carriers of the first conductivity type via the first conductivity type semiconductor layer 22 in the fourth region W4. The second electrode 15 collects carriers of the second conductivity type via the second conductivity type semiconductor layer 25 in the second region W2. The first electrode 14 and the second electrode 15 are electrically isolated by the isolation groove 16.

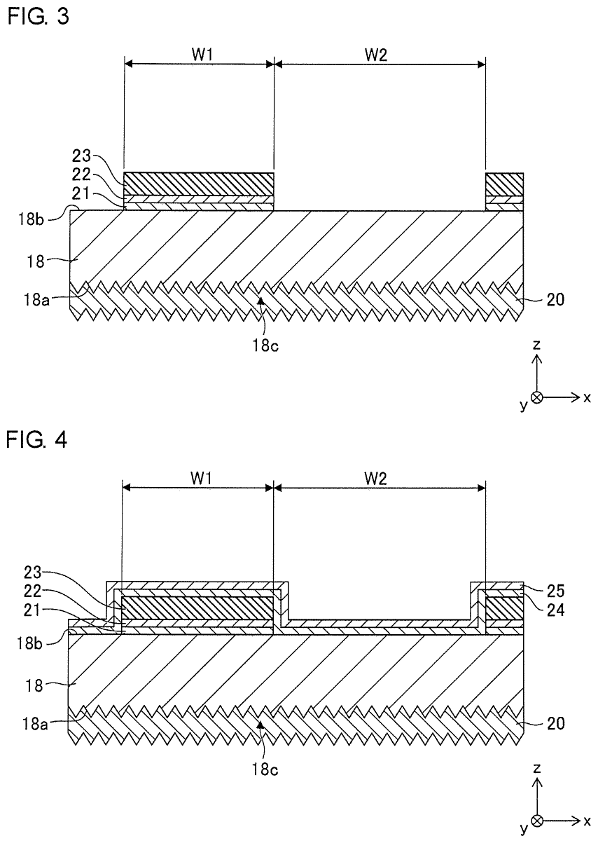

A description will now be given of a method of manufacturing the solar cell 10 with reference to FIGS. 3-10. First, the substrate 18 shown in FIG. 3 is prepared. The first principal surface 18a of the substrate 18 has a texture structure 18c, and the second principal surface 18b of the substrate 18 is flatter than the first principal surface 18a. Subsequently, the light-receiving surface protection layer 20 is formed on the first principal surface 18a, and the first amorphous layer 21, the first conductivity type semiconductor layer 22, and the insulating layer 23 are formed in the first region W1 on the second principal surface 18b.

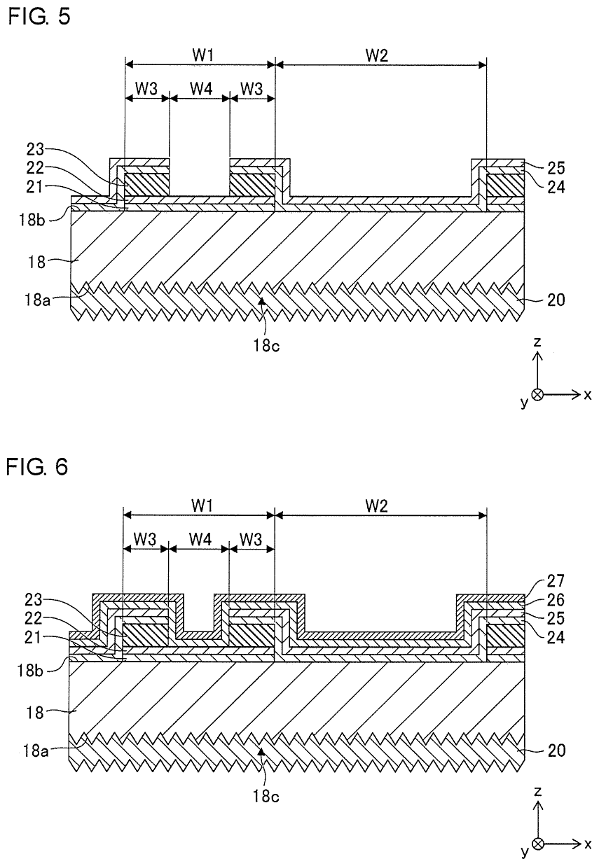

Subsequently, as shown in FIG. 4, the second amorphous layer 24 and the second conductivity type semiconductor layer 25 are formed on the insulating layer 23 in the first region W1 and on the second principal surface 18b of the substrate 18 in the second region W2. Subsequently, as shown in FIG. 5, the insulating layer 23, the second amorphous layer 24, and the second conductivity type semiconductor layer 25 in the fourth region W4 located at the center of the first region W1 are removed. This exposes the first conductivity type semiconductor layer 22 in the fourth region W4. Subsequently, as shown in FIG. 6, the transparent electrode layer 26 and the metal layer 27 are formed on the first conductivity type semiconductor layer 22 in the fourth region W4 and on the second conductivity type semiconductor layer 25 in the second region W2 and in the third region W3.

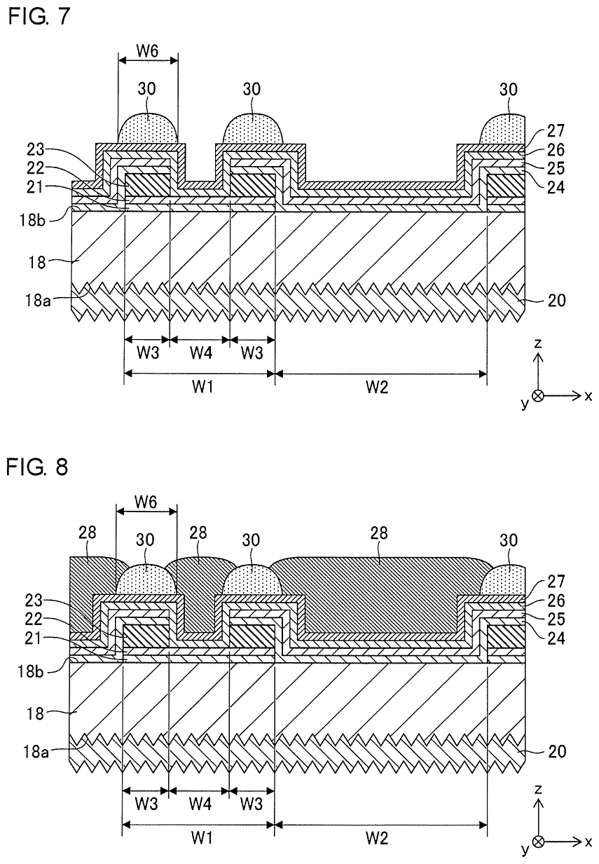

Subsequently, as shown in FIG. 7, a resist layer 30 is formed on the metal layer 27 in the resist region W6 located to correspond to the third region W3. The resist layer 30 is comprised of a mixture of resin and inorganic particles. The inorganic particles are dispersed in the resin. The resist layer 30 is formed by coating the resist region W6 with the mixture paste by using a printing technology such as screen printing and curing the mixture by heating the mixture coating or irradiating it with ultraviolet (UV) rays.

The thickness of the resist layer 30 is not less than 1 μm and not more than 30 μm, and is, for example, about 10 μm-20 μm. The thickness of the resist layer 30 need not be uniform. The thickness of the resist layer 30 may vary depending on the location. For example, the thickness of the resist layer 30 may be relatively larger near the center of the resist region W6, and the thickness of the resist layer 30 near the outer edge of the resist region W6 may be relatively small. The top surface of the resist layer 30 may consequently have a gently convex curved shape.

Subsequently, as shown in FIG. 8, the plating layer 28 is formed on the metal layer 27. The plating layer 28 is formed by using the resist layer 30 as a pattern mask and is grown on the metal layer 27, not coated with the resist layer 30, as a base point. The plating layer 28 can grow in the direction of thickness (z direction) and in the horizontal direction (x direction and y direction). Therefore, the plating layer 28 is formed to overlap the resist layer 30 in part and is formed to overhang the resist region W6. The plating layer 28 is formed such that the plating layers 28 adjacent to each other across the resist layer 30 are not joined. In other words, isolation between the plating layers 28 adjacent to each other across the resist layer 30 is maintained.

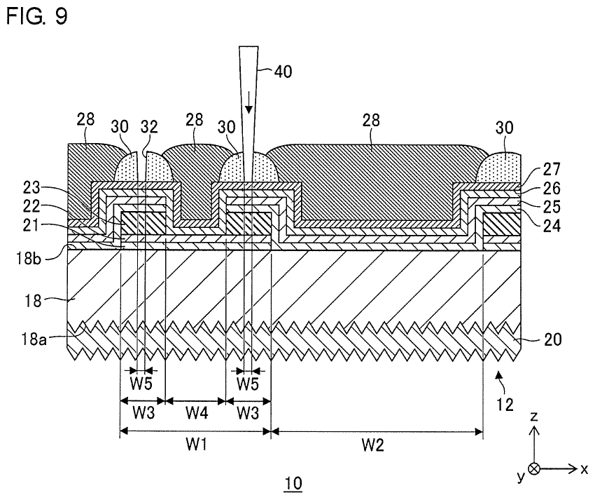

Subsequently, as shown in FIG. 9, the resist layer 30 is removed in part by irradiating the resist layer 30 from above with a laser light 40. The laser light 40 is radiated toward a portion where the aforementioned isolation region W5 should be formed. The laser light 40 is primarily absorbed by the inorganic particles included in the resist layer 30. This heats the inorganic particles and the resin included in the resist layer 30 and ablates the resist layer 30. The laser light 40 is radiated so that the resist layer 30 in the isolation region W5 irradiated with the laser is completed removed to expose the metal layer 27. This causes an opening 32 through which the metal layer 27 is exposed to be formed in the isolation region W5.

The laser light 40 is radiated as it is moved in the y direction orthogonal to the paper surface of FIG. 9. This forms the opening 32 extending in the y direction. The opening 32 extending in the y direction corresponds to the isolation groove 16 between the finger electrodes 14b and 15b extending in the y direction of FIG. 1. The laser light 40 is also radiated as it is moved in the x direction in order to form an opening located to correspond to the isolation groove 16 between the first bus bar electrode 14a and the second finger electrode 15b and between the second bus bar electrode 15a and the first finger electrode 14b. This forms the opening extending in the x direction.

As a light source for the laser light 40, solid-state laser such as Nd:YAG, rare-earth (Nd, Er, Yb)-doped fiber laser, or the like may be used. The laser light 40 may be a pulse laser or a continuous wave laser. The laser light 40 may have a Gaussian intensity distribution or a uniform top hat intensity distribution. It is preferred that the wavelength of the laser light 40 be not less than 500 nm and not more than 2000 nm, and, more preferably, not less than 800 nm and not more than 1500 nm. By selecting such a wavelength, the resist layer 30 is suitably removed, and, at the same time, a damage to the metal layer 27 is inhibited. This is because, generally, the longer the wavelength in the wavelength range from visible to near-infrared, the smaller the optical absorptance of a metal material.

Given that the metal layer 27 is made of copper (Cu), for example, the optical absorptance at the wavelength (355 nm) of the third harmonic of Nd:YAG laser is about 75%, and the optical absorptance at the wavelength (532 nm) of the second harmonic of Nd:YAG laser is about 55%. Meanwhile, the optical absorptance of copper (Cu) near 800 nm is about 10%, and the optical absorptance for the fundamental wave (1064 nm) of Nd:YAG laser is about 8%. Therefore, the damage to the metal layer 27 is more suitably reduced by using a wavelength in the near-infrared range of equal to or longer than 800 nm. By using inorganic particles having a higher optical absorptance at the wavelength of the laser light 40 than the metal layer 27, the energy of the laser light 40 is efficiently absorbed by inorganic particles, i.e., by the resist layer 30.

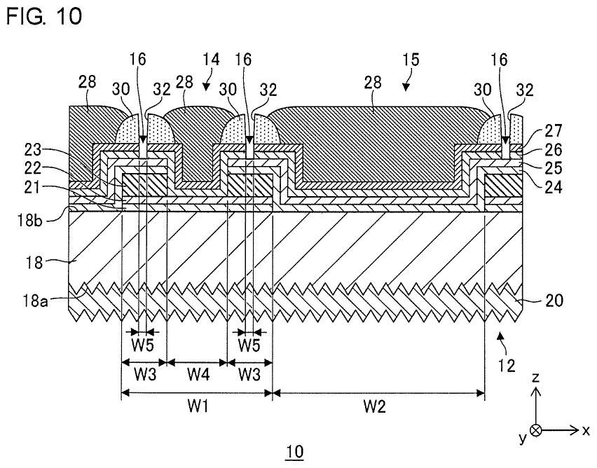

Subsequently, as shown in FIG. 10, the metal layer 27 and the transparent electrode layer 26 located in the isolation region W5 are removed via the opening 32 of the resist layer 30. The metal layer 27 and the transparent electrode layer 26 are chemically removed by an etchant. First, the metal layer 27 exposed in the opening 32 in the resist layer 30 is wet etched. This exposes the transparent electrode layer 26 in the opening 32. Subsequently, the transparent electrode layer 26 exposed in the opening 32 is wet etched. This exposes the second conductivity type semiconductor layer 25 in the opening 32 and forms the isolation groove 16. The second conductivity type semiconductor layer 25 and the second amorphous layer 24 may be additionally wet etched in the isolation region W5.

By removing the resist layer 30 subsequently, the solar cell 10 shown in FIG. 2 is completed. It is not essential to remove the resist layer 30. The resist layer 30 may remain in the solar cell 10. Therefore, the solar cell 10 may include the resist layer 30 having the opening 32 extending through the resist layer 30 in the isolation region W5.

A description will now be given of the material of the resist layer 30. As described above, the resist layer 30 is comprised of a mixture of a resin base member and inorganic particles dispersed in the resin. The resin used in the base member is a thermosetting or UV curable resin called a plating resist. For example, acrylic resin or epoxy resin may be used. The resin has a low optical absorptance at the wavelength of the laser light 40 used to form the opening 32 and can be substantially transparent for the wavelength of the laser light 40. Meanwhile, inorganic particles dispersed in the resin are embodied by a colorant like carbon black and have a high optical absorptance at the wavelength of the laser light 40. In other words, the optical absorptance of inorganic particles at the wavelength of the laser light 40 is higher than the optical absorptance of the resin used in the base member at the wavelength of the laser light 40. According to this embodiment, the resist layer 30 is suitably ablated by irradiating it with a laser a small number of times, by using the resist layer 30 including inorganic particles in the resin at an appropriate density. For example, the resist layer 30 having a thickness of about 10 μm-20 μm is removed by a single session of laser irradiation and the damage to the metal layer 27 underneath the resist layer 30 is prevented, by configuring the density of carbon black to be not less than 0.3 weight % and not more than 2 weight %.

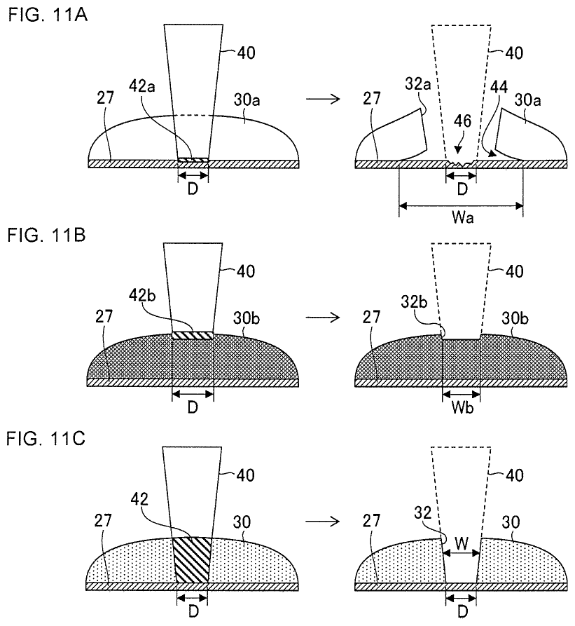

FIGS. 11A-11C are detailed view of a step of forming an opening in the resist layer by irradiating the resist layer with the laser light 40. Inorganic particles are included in the resist layer at different densities in FIGS. 11A-11C.

FIG. 11A shows a comparative example in which inorganic particles are not included in a resist layer 30a. In the case inorganic particles are not included in the resist layer 30a, the irradiating laser light 40 is transmitted through the resist layer 30a and is incident on the metal layer 27 beneath the resist layer 30a. The laser light 40 is absorbed by the metal layer 27, causing ablation on the surface of the metal layer 27. Since an ablation region 42a on the surface of the metal layer 27 is coated with the resist layer 30a, the metal material vaporized by the ablation is contained at the interface, creating a high-pressure state. As a result, a high pressure is exerted on the resist layer 30a so that a portion of the resist layer 30a is removed by “lift-off” as if the layer is ruptured, and an opening 32a is formed accordingly. In this process, the range in which the resist layer 30a is removed could be larger than a irradiation diameter D of the laser light 40. The rupture in the resist layer 30a causes the end of the remaining resist layer 30a to be exfoliated as it is lifted from the metal layer 27, creating a gap 44 between the resist layer 30a and the metal layer 27. As a result, the opening width Wa through which the metal layer 27 and the transparent electrode layer 26 are removed in the subsequent wet etching step would be twice or larger than the irradiation diameter D of the laser light 40, which could result in a large isolation width of the isolation groove 16. Ablation on the surface of the metal layer 27 could produce a damage 46 on the metal layer 27. Not only the metal layer 27 but also the transparent electrode layer 26 or the semiconductor layer further beneath may be damaged, depending on the intensity of the laser light 40.

FIG. 11B shows a comparative example in which high-density inorganic particles are included in the resist layer 30b. In the case that high-density (e.g., 2.5 weight % or higher) carbon black is included in the resist layer 30b, the major portion of the irradiating laser light 40 is absorbed near the surface of the resist layer 30b and is not transmitted further below. As a result, an ablation region 42b produced by the laser light 40 remains near the surface of the resist layer 30b so that a relatively shallow opening 32b is formed. The opening width Wb of the opening 32b in this case is substantially identical to the irradiation diameter D of the laser light 40 so that the isolation width of the isolation groove 16 is configured to be smaller than that of the comparative example of FIG. 11A. However, the resist layer 30 need be irradiated with a laser a plurality of times in order to cause the opening 32b to extend through the resist layer 30.

FIG. 11C shows an example in which low-density inorganic particles are included in the resist layer 30. In the case low-density carbon black (e.g., about 0.5 weight %) is included in the resist layer 30, the laser light 40 is attenuated gradually by being absorbed by the low-density carbon black as the light is transmitted through the resist layer 30. As a result, the laser light 40 is absorbed in a region 42 that extends over the entirety of the direction of thickness of the resist layer 30 to cause ablation. Since the metal layer 27 is irradiated with the laser light 40 attenuated to have a low intensity, the laser light 40 produces, if ever, only soft ablation at the interface between the metal layer 27 and the resist layer 30. As a result, a lift-off that is milder than that of the comparative example of FIG. 11A is produced so that the opening 32 having the opening width W substantially identical to the irradiation diameter D of the laser light 40 is formed by a single session of laser irradiation. Since the lift-off effect is milder, exfoliation of the resist layer 30 that remains is prevented. Since the opening 32 of the resist layer 30 is tapered such that the opening width W grows smaller toward the metal layer 27, the isolation groove 16 formed in the subsequent step is configured to have a smaller isolation width.

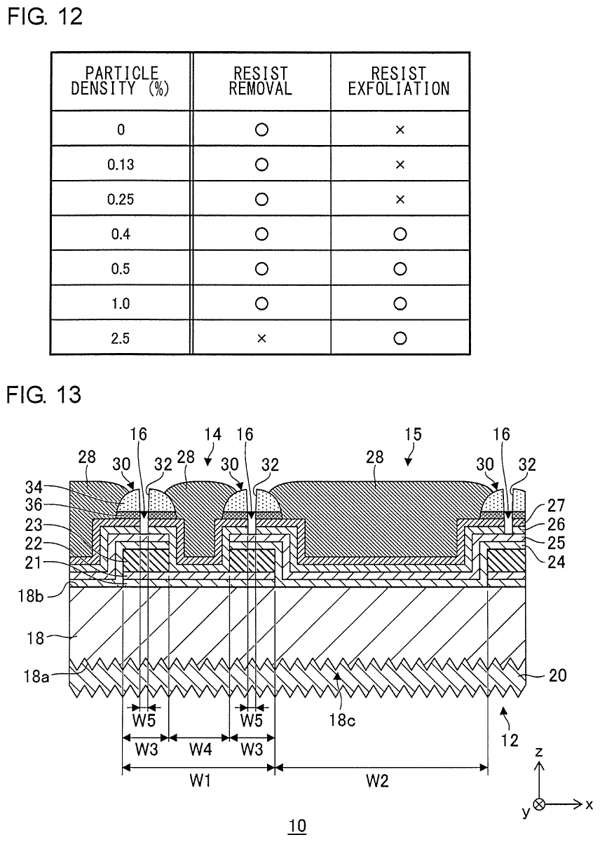

FIG. 12 shows the workability with which to work the opening 32 by laser irradiation that results when the density of inorganic particles included in the resist layer 30 is changed. “Resist removal” and “resist exfoliation” are listed as two indices of the workability of the opening 32. “x” is entered in the “resist removal” field when the resist layer 30 remains in a region (isolation region W5) irradiated by the laser light 40, and “0” is entered when the resist layer 30 is successfully removed without remaining in the irradiated region. “x” is entered in the “resist exfoliation” field when exfoliation of the resist layer 30 is identified around the region irradiated by the laser light 40, and “o” is entered when exfoliation is not identified.

In the example shown in FIG. 12, carbon black is used as inorganic particles, and the fundamental wave of Nd:YAG (wavelength is 1064 nm) having a top hat distribution is used as the laser light 40. The laser light 40 is a nanosecond pulsed laser, and each irradiated region is irradiated by only one pulse. The irradiation intensity of the laser light 40 is 0.8 J/cm²-1.4 J/cm². The figure reveals that “resist exfoliation” is indicated as “x” when the density of carbon black is 0.25 weight % or lower. This is considered to be because of hard lift-off as shown in FIG. 11A. In the case the density of carbon black is not less than 0.3 weight % and not more than 2 weight %, “resist removal” and “resist exfoliation” are indicated as “o”, which is considered to show that suitable ablation as shown in FIG. 11C has occurred. Meanwhile, the figure reveals that “resist removal” is indicated as “x” in the case the density of carbon black is 2.5 weight % or higher. This is considered to be because the resist layer 30 cannot be removed sufficiently with a single session of laser irradiation, as shown in FIG. 11B.

According to this embodiment, the opening 32 having a small opening width W is formed in the resist layer 30 by irradiating it with a laser a small number of times, by using the resist layer 30 in which inorganic particles having a high optical absorptance for the laser light 40 are dispersed in the resin base member having a low optical absorptance for the laser light 40. This secures a small isolation width of the isolation groove 16 formed in the metal layer 27 and the transparent electrode layer 26 in the subsequent wet etching step. By configuring the isolation groove 16 to have a small width, the area of contact between the metal layer 27/transparent electrode layer 26 with the semiconductor layers 22, 25 is increased, and the power collection efficiency of the first electrode 14 and the second electrode 15 is increased. In this way, the power generation efficiency of the solar cell 10 is improved.

According to this embodiment, ablation caused by optical absorption in inorganic particles included in the resist layer 30 equalizes the amount of energy absorbed per a unit volume of the resist layer 30 even if the thickness of the resist layer 30 in the region irradiated by the laser light 40 is not uniform. In the case the resist layer 30 is patterned by screen printing, the printing position of the resist layer 30 may be slightly shifted depending on the precision of the printing position. The top surface of the resist layer 30 printed has a convexly curved shape, and the thickness may vary depending on the location. Therefore, the impact from a shift in the printing position could produce a variation in the thickness at different positions of laser irradiation. Even when such a variation occurs during the manufacturing, the energy is uniformly absorbed by the resist layer 30 in the region irradiated by the laser light 40 to cause ablation so that the variation in the opening width W of the opening 32 thus formed is reduced. This secures a uniform isolation width of the isolation groove 16 and increases the reliability of the solar cell 10.

According to this embodiment, the resist layer 30 is removed over the entirety of the direction of thickness of the resist layer 30 in a single session of laser irradiation, by adjusting the density of inorganic particles included in the resist layer 30. This reduces the cost for patterning the opening 32. In particular, the combined use of screen printing and laser irradiation reduces the cost as compared with the case of patterning the resist layer 30 by using photolithographic technique.

One embodiment of the disclosure is summarized below. A method of manufacturing a solar cell (10) according to an embodiment includes:

forming a metal layer (27) on a semiconductor substrate (18);
forming a resist=layer (30) on the metal layer (27), the resist layer including a resin and inorganic particles having a higher optical absorptance at a predetermined wavelength than the resin;
forming an opening (32) through which the metal layer (27) is exposed, by irradiating the resist layer (30) with a laser light (40) having the predetermined wavelength to remove the resist layer (30); and
wet etching the metal layer (27) exposed in the opening (32).

The inorganic particles may have a higher optical absorptance at the predetermined wavelength than the metal layer (27).

The method may further include: forming, before irradiation with the laser light (40) having the predetermined wavelength, a plating layer (28) on the metal layer (27) by using the resist layer (30) as a pattern mask.

The opening (32) of the resist layer (30) may be tapered such that an opening width grows smaller toward the metal layer (27).

The resist layer (30) may be screen-printed on the metal layer (27).

The thickness of the resist layer (30) may be not less than 1 μm and not more than 30 μm. A density of the inorganic particles included in the resist layer (30) may be not less than 0.3 weight % and not more than 2 weight %.

The predetermined wavelength may be not less than 500 nm and not more than 2000 nm.

The laser light (40) may have a top hat intensity distribution.

The method may further include: forming a first conductivity type semiconductor layer (22) provided in a first region (W1) on the semiconductor substrate (18), an insulating layer (23) provided in a partial region (a third region W3) adjacent to an edge of the first region (W1) on the first conductivity type semiconductor layer (22), and a second conductivity type semiconductor layer (25) provided in a second region (W2) on the semiconductor substrate (18) adjacent to the first region (W1) and provided on the insulating layer (23).

The metal layer (27) may be formed on the first conductivity type semiconductor layer (22)e, the insulating layer (23), and the second conductivity type semiconductor layer (25).
The opening (32) of the resist layer (30) may be formed to be aligned with the insulating layer (23).

A solar cell according to an embodiment includes:

a semiconductor substrate (18);
a first conductivity type semiconductor layer (22) provided in a first region (W1) on the semiconductor substrate (18);
an insulating layer (23) provided in a partial region (third region W3) adjacent to the first region (W1) on the first conductivity type semiconductor layer (22);
a second conductivity type semiconductor layer (25) provided in a second region (W2) on the semiconductor substrate (18) adjacent to the first region (W1) and provided on the insulating layer (23);
a metal layer (27) provided on the first conductivity type semiconductor layer (22), the insulating layer (23), and the second conductivity type semiconductor layer (25); and
a resist layer (30) that is provided on the metal layer (27) and includes a resin and inorganic particles, wherein
the metal layer (27) and the resist layer (30) have an opening (32) that extends through the metal layer (27) or the resist layer (32) at a position overlapping the insulating layer (23), and
the opening (32) of the resist layer (30) is tapered such that an opening width grows smaller toward the metal layer (27).

FIG. 13 is a cross-sectional view showing the structure of the solar cell 10 according to a variation. This variation differs from the embodiment in that the resist layer 30 has a first resist layer 34 and a second resist layer 36. The second resist layer 36 is provided between the metal layer 27 and the first resist layer 34 and includes inorganic particles at a higher density than the first resist layer 34. For example, the density of inorganic particles included in the first resist layer 34 is not less than 0.3 weight % and not more than 2 weight %, and the density of inorganic particles included in the second resist layer 36 is 2.5 weight % or higher. The thickness of the second resist layer 36 is smaller than the thickness of the first resist layer 34. For example, the thickness of the first resist layer 34 is not less than 5 μm and not more than 30 μm, and the thickness of the second resist layer 36 is not less than 1 μm and not more than 3 μm.

According to the variation, the amount of light absorbed by the resist layer 30 near the surface of the metal layer 27 is increased by providing the second resist layer 36 with a higher density of inorganic particles at the interface between the metal layer 27 and the first resist layer 34. This promotes ablation of the resist layer 30 near the surface of the metal layer 27 and ensures that the resist layer 30 in the isolation region W5 irradiated with the laser light 40 is properly removed. Since the intensity of the laser light 40 reaching the metal layer 27 is further reduced, the damage to the metal layer 27 caused by irradiation with the laser light 40 is further reduced. In the case that the second harmonic (532 nm) of Nd:YAG laser is used, the resist layer 30 is properly removed and, at the same time, the metal layer 27 is prevented from being damaged. In further accordance with the variation, it is also possible to secure a large range of irradiation condition (process window) of the laser light 40 capable of forming the opening 32 properly. In the case a picosecond pulsed laser having a wavelength 532 nm is used, for example, the opening 32 for which no exfoliation occurs in the surrounding part is formed by a single session of laser irradiation using the laser light 40 of about 0.45 J/cm²-4.5 J/cm².

The resist layer (30) may include a first resist layer including a resin and inorganic particles and a second resist layer including a resin and including inorganic particles at a higher density than the first resist layer. The second resist layer may be formed between the metal layer (27) and the first resist layer, and the second resist layer may have a smaller thickness than the first resist layer.

The embodiment of the present invention is not limited to those described above and appropriate combinations or replacements of the features of the embodiment and the variations are also encompassed by the present invention.

It should be understood that the invention is not limited to the above-described embodiments and modifications but may be further modified into various forms on the basis of the spirit of the invention. Additionally, those modifications are included in the scope of the invention.

What is claimed is:

1. A method of manufacturing a solar cell, comprising:
forming a metal layer on a semiconductor substrate;
forming a resist layer on the metal layer, the resist layer including a resin and inorganic particles having a higher optical absorptance at a predetermined wavelength than the resin;
forming an opening through which the metal layer is exposed, by irradiating the resist layer with a laser light having the predetermined wavelength to remove the resist layer; and
wet etching the metal layer exposed in the opening.

2. The method of manufacturing a solar cell according to claim 1, wherein
the inorganic particles may have a higher optical absorptance at the predetermined wavelength than the metal layer.

3. The method of manufacturing a solar cell according to claim 1, further comprising:
forming, before irradiation with the laser light having the predetermined wavelength, a plating layer on the metal layer by using the resist layer as a pattern mask.

4. The method of manufacturing a solar cell according to claim 1, wherein
the opening of the resist layer may be tapered such that an opening width grows smaller toward the metal layer.

5. The method of manufacturing a solar cell according to claim 1, wherein
the resist layer is screen-printed on the metal layer.

6. The method of manufacturing a solar cell according to claim 1, wherein
the thickness of the resist layer is not less than 1 μm and not more than 30 μm, and a density of the inorganic particles included in the resist layer is not less than 0.3 weight % and not more than 2 weight %.

7. The method of manufacturing a solar cell according to claim 1, wherein
the resist layer includes a first resist layer including the resin and the inorganic particles and a second resist layer including the resin and including the inorganic particles at a higher density than the first resist layer, and
the second resist layer is formed between the metal layer and the first resist layer, and the second resist layer has a smaller thickness than the first resist layer.

8. The method of manufacturing a solar cell according to claim 1, wherein
the predetermined wavelength is not less than 500 nm and not more than 2000 nm.

9. The method of manufacturing a solar cell according to claim 1, wherein
the laser light has a top hat intensity distribution.

10. The method of manufacturing a solar cell according to claim 1, further comprising:
forming a first conductivity type semiconductor layer provided in a first region on the semiconductor substrate, an insulating layer provided in a partial region adjacent to an edge of the first region on the first conductivity type semiconductor layer, and a second conductivity type semiconductor layer provided in a second region on the semiconductor substrate adjacent to the first region and provided on the insulating layer, wherein
the metal layer is formed on the first conductivity type semiconductor layer, the insulating layer, and the second conductivity type semiconductor layer, and
the opening of the resist layer is formed to be aligned with the insulating layer.

11. A solar cell comprising:
a semiconductor substrate;
a first conductivity type semiconductor layer provided in a first region on the semiconductor substrate;
an insulating layer provided in a partial region on the first conductivity type semiconductor layer adjacent to the first region;
a second conductivity type semiconductor layer provided in a second region on the semiconductor substrate adjacent to the first region and provided on the insulating layer;
a metal layer provided on the first conductivity type semiconductor layer, the insulating layer, and the second conductivity type semiconductor layer; and
a resist layer that is provided on the metal layer and includes a resin and inorganic particles, wherein
the metal layer and the resist layer have an opening that extends through the metal layer or the resist layer at a position overlapping the insulating layer, and
the opening of the resist layer is tapered such that an opening width grows smaller toward the metal layer.
